(19) United States
(12) Patent Application Publication
(10) Pub. No.: US 2021/0130955 A1
(43) Pub. Date: May 6, 2021

(54) FILM FORMING APPARATUS AND FILM FORMING METHOD

(71) Applicant: Tokyo Electron Limited, Tokyo (JP)

(72) Inventors: Hiroshi NAGAIKE, Kurokawa-gun, Miyagi (JP); Daisuke YOSHIKOSHI, Kurokawa-gun, Miyagi (JP); Takao FUNAKUBO, Kurokawa-gun, Miyagi (JP); Takahisa IWASAKI, Hillsboro, OR (US); Chiju HSIEH, Kurokawa-gun, Miyagi (JP); Yuki AZUMA, Kurokawa-gun, Miyagi (JP); Hideyuki KOBAYASHI, Kurokawa-gun, Miyagi (JP)

(21) Appl. No.: 16/976,556

(22) PCT Filed: Jul. 23, 2019
(86) PCT No.: PCT/JP2019/028806

§ 371 Date: Aug. 28, 2020

(30) Foreign Application Priority Data
Jul. 27, 2018 (JP) 2018-141369

(51) Int. Cl. C23C 16/455; C23C 16/52; H01L 21/3065

(52) U.S. Cl. CPC C23C 16/45536; H01L 21/3065; C23C 16/45502; C23C 16/52

(57) ABSTRACT

A film forming apparatus configured to form a predetermined film on a substrate by PEALD includes a processing container configured to airtightly accommodate the substrate; and a placing table on which the substrate is placed within the processing container. The processing container includes an exhaust opening through which an inside of the processing container is exhausted; an exhaust path configured to connect the exhaust opening and a processing space above the placing table within the processing container; and a partition wall configured to separate a processing space side from an exhaust opening side in the exhaust path. The partition wall includes a flow path configured to connect the processing space side and the exhaust opening side, and the partition wall is formed such that the exhaust opening side is not seen from the processing space side when an extension direction of the exhaust path is viewed from a top.

### TECHNICAL FIELD

The various aspects and embodiments described herein pertain generally to a film forming apparatus and a film forming method.

### BACKGROUND

Patent Document 1 discloses a film forming method for forming an oxide film on a substrate by plasma-enhanced atomic layer deposition (PEALD). In this film forming method, an oxide film, such as a silicon oxide film, is formed by the PEALD by repeating a cycle including following processes (i) and (ii). The process (i) includes supplying a precursor to a reaction space where a substrate is placed, for example, to adsorb the precursor on the substrate and purging to remove a non-adsorbed precursor from the substrate. The process (ii) includes exposing the adsorbed precursor to plasma, such as oxygen, to cause surface reaction to the adsorbed precursor and purging to remove a non-reacted component from the substrate.

### PRIOR ART DOCUMENT

Patent Document 1: Japanese Patent Laid-open Publication No. 2015-061075

### DISCLOSURE OF THE INVENTION

### Problems to be Solved by the Invention

The technology disclosed herein can improve a productivity when a film is formed by PEALD.

### Means for Solving the Problems

In one exemplary embodiment, a film forming apparatus configured to form a predetermined film on a substrate by PEALD includes a processing container configured to airtightly accommodate therein the substrate; and a placing table on which the substrate is placed within the processing container. The processing container includes an exhaust opening through which an inside of the processing container is exhausted; an exhaust path configured to connect the exhaust opening and a processing space located above the placing table within the processing container; and a partition wall configured to separate a processing space side from an exhaust opening side in the exhaust path. The partition wall includes a flow path configured to connect the processing space side and the exhaust opening side, and the partition wall is formed such that the exhaust opening side is not seen from the processing space side when an extension direction of the exhaust path is viewed from a top.

### Effect of the Invention

According to the present disclosure, it is possible to improve the productivity when the film is formed by the PEALD.

### BRIEF DESCRIPTION OF THE DRAWINGS

FIG. 1 is a longitudinal cross-sectional view schematically illustrating a configuration of a plasma processing apparatus as a film forming apparatus according to an embodiment.

FIG. 2 is a partial enlarged view of FIG. 1.

FIG. 3 is a plan view of a partition wall of FIG. 1.

FIG. 4 is a flowchart provided to explain a processing on a wafer W in the plasma processing apparatus illustrated in FIG. 1.

FIG. 5 shows another example of a partition wall.

FIG. 6 shows yet another example of a partition wall.

### DETAILED DESCRIPTION

First, a conventional film forming method disclosed in Patent Document 1 will be described.

In a manufacturing process of a semiconductor device, a processing such as film forming processing is performed on a target substrate (hereinafter, referred to as “substrate”) such as a semiconductor wafer. A film forming method may be, for example, ALD, and a film forming apparatus repeats a predetermined cycle to deposit atomic layers one by one and thus forms a desired film on the substrate.

In the method for forming the oxide film on the substrate by the PEALD according to Patent Document 1, the cycle including the following processes (i) and (ii) is repeated as described above. In the process (i), the precursor is supplied to the reaction space to adsorb the precursor on the substrate and then, the purging is performed to remove the non-adsorbed precursor from the substrate. In the process (ii), the adsorbed precursor is exposed to the plasma to cause the surface reaction to the adsorbed precursor and then, the purging is performed to remove the non-reacted component from the substrate.

Herein, even if radicals (oxygen radicals or the like) contained in the plasma that causes the surface reaction to the precursor during film formation are excessively supplied near the substrate, they do not have a bad influence on the film formation. Excess radicals simply do not contribute to modification (reaction) of an adsorption layer formed of the precursor. Therefore, during the film formation, a sufficient amount of radicals is supplied near the substrate such that the precursor on the entire surface of the substrate can be modified by being reacted with the radicals. Thus, it is possible to secure the stability of the film formation such as film thickness uniformity.

The radicals that do not contribute to the modification on the surface of the substrate reach other places, such as an inner wall of a processing container where the substrate is accommodated, than the substrate. As a result, if the precursor exists in the places where the radicals reach, the radicals react with the precursor to generate an unnecessary reaction product (hereinafter, referred to as “deposit”). The generated deposit can be removed by dry cleaning with plasma or the like. However, radicals, such as oxygen (O) radicals, have long lifetime, and radicals that do not react with the substrate may generate the deposit in a place where it is difficult to remove the deposit by the dry cleaning (for example, a portion which is several 10 cm to several m apart from the substrate and placed at an exhaust-direction downstream side than the processing container).

Methods for removing the deposit include dry cleaning with a nitrogen trifluoride (NF₃) gas and the like or cleaning with remote plasma. However, it requires a long time to remove the deposit generated in the place, such as the portion at the exhaust-direction downstream side than the processing container, far from the region where plasma is formed. Further, if it is technically difficult to perform these cleaning processes, a portion to which the deposit adheres may be removed and then, cleaning with a chemical solution and the like may be performed. However, even in this case, it requires a long time to remove the deposit. If it requires long time to remove the deposit, the productivity deteriorates.

In addition to the above-described methods for removing the deposit, there is a method of suppressing the adhesion of the deposit by controlling a temperature only. For example, there is a method in which a portion where the adhesion of the deposit is suppressed has a higher temperature than a substrate serving as the film forming target because the deposit is generally likely to adhere to a low-temperature portion. For example, if the substrate is set to 20° C. and an inner wall of the apparatus is set to 60° C., the amount of deposit adhering to the inner wall of the apparatus can be reduced. However, the film formation by the ALD progresses as the temperature of the substrate increases. For this reason, in many cases, when the film formation is performed by the ALD, it is difficult to set the portion where the adhesion of the deposit is to be suppressed to a higher temperature than the substrate serving as the film forming target.

Hereinafter, a film forming apparatus and a film forming method according to the present exemplary embodiment for suppressing the adhesion of the reaction product, which has been generated by the radicals that do not contribute to the surface reaction on the substrate, to a place where it is difficult to remove the deposit by the dry cleaning when the film formation is performed by the PEALD will be described with reference to the accompanying drawings. Further, in the present specification and the drawings, substantially the same components will be denoted by the same reference numerals and redundant descriptions thereof will be omitted.

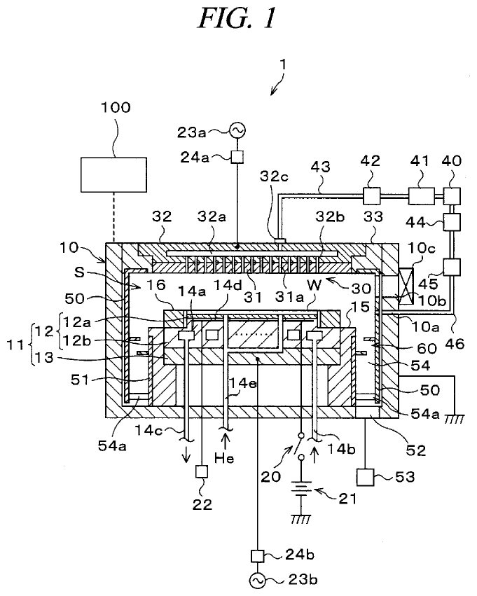

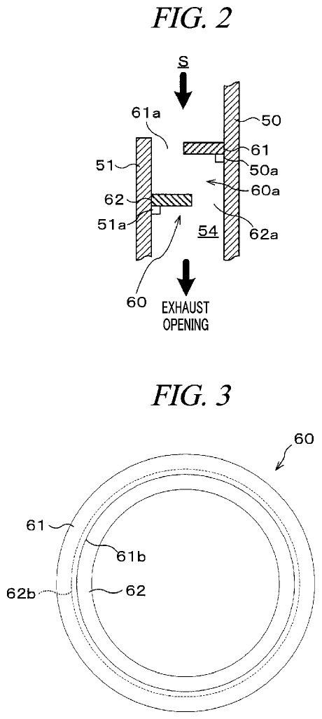

FIG. 1 is a longitudinal cross-sectional view schematically illustrating the configuration of a plasma processing apparatus as a film forming apparatus according to the present exemplary embodiment. FIG. 2 is a partial enlarged view of FIG. 1. FIG. 3 is a plan view of a partition wall which will be described later. Further, in the present exemplary embodiment, a plasma processing apparatus 1 will be described as, for example, a capacitively coupled plasma processing apparatus capable of performing both a film formation and an etching. Furthermore, the plasma processing apparatus 1 is configured to form a SiO₂ film with O radicals.

As illustrated in FIG. 1, the plasma processing apparatus 1 includes an approximately cylindrical processing container 10. In the processing container 10, plasma is formed and a semiconductor wafer (hereinafter, referred to as “wafer”) W serving as the substrate is airtightly accommodated. In the present exemplary embodiment, the processing container 10 is configured to process a wafer W having a diameter of 300 mm. The processing container 10 is formed of, for example, aluminum, and anodic oxidation is performed on the inner wall surface thereof. This processing container 10 is frame-grounded.

A placing table 11 on which the wafer W is placed is accommodated within the processing container 10.

The placing table 11 includes an electrostatic chuck 12 and an electrostatic chuck placing plate 13. The electrostatic chuck 12 includes a placing member 12a on an upper side thereof and a base member 12b on a lower side thereof. The electrostatic chuck placing plate 13 is provided under the base member 12b of the electrostatic chuck 12. Also, the base member 12b and the electrostatic chuck placing plate 13 are formed of a conductive material such as metal, for example, aluminum (Al), and function as a lower electrode.

The placing member 12a has a structure in which an electrode is provided between a pair of insulating layers. The electrode is connected to a DC power supply 21 via a switch 20. Further, the wafer W is attracted onto a placing surface of the placing member 12a by an electrostatic force which is generated when a DC voltage is applied to the electrode from the DC power supply 21.

Further, a coolant flow path 14a is formed within the base member 12b. A coolant is supplied into the coolant flow path 14a from a chiller unit (not illustrated) provided outside the processing container 10 through a coolant inlet line 14b. The coolant supplied into the coolant flow path 14a returns back to the chiller unit through a coolant outlet line 14c. As such, the coolant, for example, cooling water is circulated in the coolant flow path 14a, so that the placing table 11 and the wafer W placed on the placing table 11 can be cooled to a predetermined temperature.

Furthermore, a heater 14d serving as a heating device is provided above the coolant flow path 14a of the base member 12b. The heater 14d is connected to a heater power supply 22, and when a voltage is applied from the heater power supply 22, the placing table 11 and the wafer W placed on the placing table 11 can be heated to a predetermined temperature. Also, the heater 14d may be provided in the placing member 12a.

Besides, a gas flow path 14e through which a cold heat transfer gas (backside gas), such as a helium gas or the like, is supplied to a rear surface of the wafer W from a gas source (not illustrated) is provided in the placing table 11. The wafer W attracted and held on the placing surface of the placing table 11 by the electrostatic chuck 12 can be controlled to a predetermined temperature by using the cold heat transfer gas.

The placing table 11 configured as described above is supported on an approximately cylindrical support member 15 provided on a bottom portion of the processing container 10. The support member 15 is formed of an insulator, for example, ceramics and the like.

An annular focus ring 16 may be provided on a peripheral portion of the base member 12b of the electrostatic chuck 12 to surround the side of the placing member 12a. The focus ring 16 is provided coaxially with respect to the electrostatic chuck 12. The focus ring 16 is provided to improve the uniformity in plasma processing. Also, the focus ring 16 is formed of a material appropriately selected depending on the plasma processing such as etching, and may be formed of, for example, silicon or quartz.

Above the placing table 11, a shower head 30 serving as a plasma source is provided to face the placing table 11. The shower head 30 functions as an upper electrode and includes an electrode plate 31 disposed to face the wafer W on the placing table 11 and an electrode support 32 provided on the electrode plate 31. Further, the shower head 30 is supported on an upper portion of the processing container 10 with an insulating shield member 33 therebetween.

The electrode plate 31 and the electrostatic chuck placing plate 13 function as a pair of electrodes (upper electrode and lower electrode). A plurality of gas discharge holes 31a is formed in the electrode plate 31. The gas discharge holes 31a are configured to supply a processing gas into a processing space S located above the placing table 11 within the processing container 10. Further, the electrode plate 31 is formed of, for example, silicon (Si).

The electrode support 32 is configured to support the electrode plate 31 in a detachable manner, and is formed of a conductive material, for example, aluminum having an anodically oxidized surface. A gas diffusion space 32a is formed within the electrode support 32. A plurality of gas flow holes 32b communicating with the gas discharge holes 31a are formed from the gas diffusion space 32a. Further, the electrode support 32 is connected to a gas source group 40 via a flow rate controller group 41, a valve group 42, a gas supply line 43 and a gas inlet opening 32c to supply the processing gas into the gas diffusion space 32a.

The gas source group 40 has a plurality of gas sources for gases required for the plasma processing. In the plasma processing apparatus 1, a processing gas from one or more gas sources selected from the gas source group 40 is supplied into the gas diffusion space 32a via the flow rate controller 41, the valve group 42, the gas supply line 43 and the gas inlet opening 32c. Further, the processing gas supplied into the gas diffusion space 32a is introduced in a shower shape to be supplied into the processing space S through the gas flow holes 32b and the gas discharge holes 31a.

To supply the processing gas into the processing space S within the processing container 10 without using the shower head 30, a gas inlet hole 10a is formed at a side wall of the processing container 10. The number of gas inlet holes 10a may be one, or two or more. The gas inlet hole 10a is connected to the gas source group 40 via a flow rate controller group 44, a valve group 45 and a gas supply line 46.

Further, a deposit shield (hereinafter, referred to as “shield”) 50 is detachably provided on the side wall of the processing container 10 along an inner peripheral surface thereof. The shield 50 is configured to suppress adhesion of a deposit or an etching by-product, which is generated during the film formation, to the inner wall of the processing container 10, and may be formed of, for example, aluminum coated with ceramic such as Y₂O₃. Furthermore, a deposit shield (hereinafter, referred to as “shield”) 51, which is identical to the shield 50, is detachably provided on an outer circumference surface of the support member 15 to face the shield 50.

An exhaust opening 52 for exhausting the inside of the processing container 10 is formed at the bottom portion of the processing container 10. The exhaust opening 52 is connected to an exhaust device 53, for example, a vacuum pump, and the exhaust device 53 is configured to depressurize the inside of the processing container 10.

Further, the processing container 10 includes therein an exhaust path 54 that connects the above-described processing space S and the exhaust opening 52. The exhaust path 54 is partitioned by an inner circumference surface of the side wall of the processing container 10 including an inner circumference surface of the shield 50 and an outer peripheral surface of the support member 15 including an outer peripheral surface of the shield 51. A gas within the processing space S is exhausted to the outside of the processing container 10 via the exhaust path 54 and the exhaust opening 52.

A flat exhaust plate 54a is provided at an end portion on the exhaust opening 52 side of the exhaust path 54, i.e., at an end portion at an exhaust-direction downstream side, to block the exhaust path 54. Herein, the exhaust plate 54a includes through-holes and thus does not interrupt the exhaust flow within the processing container 10 via the exhaust path 54 and the exhaust opening 52. The exhaust plate 54a is formed of, for example, aluminum coated with ceramic such as Y₂O₃.

Also, within the processing container 10, a partition wall 60 is provided to separate the processing space S side from the exhaust opening 52 side in the exhaust path 54.

The partition wall 60 includes a flow path 60a that connects the processing space S side and the exhaust opening 52 side in the exhaust path 54 as illustrated in FIG. 2.

The partition wall 60 is configured to suppress the radicals generated within the processing space S during the plasma processing from reaching the exhaust opening 52 without being deactivated. In the present exemplary embodiment, the gas within the processing space S passes through the flow path 60a of the partition wall 60. Also, the partition wall 60 is formed such that the exhaust opening 52 side cannot be seen from the processing space S side when an extension direction (vertical direction in FIG. 2) of the exhaust path 54 is viewed from the top. Therefore, when the radicals within the processing space S is discharged from the processing space S and passes through the flow path 60a, the radicals are deactivated by being collided with a surface of a structure, which forms the flow path 60a, and then reach the exhaust opening 52.

Hereinafter, the partition wall 60 will be described in detail.

The partition wall 60 includes a first member 61 and a second member 62 as illustrated in FIG. 2. The first member 61 protrudes inwards from the inner circumference surface (specifically, inner circumference surface of the shield 50) of the side wall of the processing container 10 which forms the exhaust path 54. Also, the first member 61 has a gap 61a with respect to the inner circumference surface and covers a part of an outer side of the exhaust path 54. The second member 62 protrudes outwards from the outer circumference surface (specifically, outer circumference surface of the shield 51) of the support member 15 which forms the exhaust path 54. Also, the second member 62 has a gap 62a with respect to the outer circumference surface and covers a part of an inner side of the exhaust path 54. Further, as illustrated in FIG. 3, each of the first member 61 and the second member 62 is formed into a circular ring shape when viewed from the top. A tip end portion 61b of the first member 61 and a tip end portion 62b of the second member 62 overlap with each other along the entire circumferential direction when viewed from the top.

In the present exemplary embodiment, the flow path 60a is formed by the first member 61, the second member 62, the gap 61a and the gap 62a as illustrated in FIG. 2.

The first member 61 is supported by a first protrusion 50a serving as a first support and the second member 62 is supported by a second protrusion 51a serving as a second support. The first protrusion 50a protrudes inwards from the shield 50 and the second protrusion 51a protrudes outwards from the shield 51.

The partition wall 60, i.e., the first member 61 and the second member 62, is formed of a material, for example, metal, alumina or Si, having a high recombination coefficient for the O radicals.

Referring to FIG. 1 again, the plasma processing apparatus 1 is connected to a first radio frequency power supply 23a via a first matching device 24a and to a second radio frequency power supply 23b via a second matching device 24b.

The first radio frequency power supply 23a is configured to generate a radio frequency power for plasma formation. The first radio frequency power supply 23a supplies a radio frequency power having a frequency of from 27 MHz to 100 MHz, for example, 40 MHz, to the electrode support 32 of the shower head 30. The first matching device 24a has a circuit configured to match an output impedance of the first radio frequency power supply 23a with an input impedance of a load side (the electrode support 32 side).

The first radio frequency power supply 23a can generate a continuously oscillating radio frequency power as well as a pulse-shaped power in which a period with power of an ON level and a period with power of an OFF level are alternated periodically. Also, the OFF level of the pulse-shaped power may not be zero. That is, the first radio frequency power supply 23a may also generate a pulse-shaped power in which a period with power of a high level and a period with power of a low level are alternated periodically.

The first radio frequency power supply 23a supplies a radio frequency power equal to or larger than 50 W and smaller than 500 W when performing continuous oscillation. Also, the first radio frequency power supply 23a supplies a radio frequency power which is of the pulse wave shape having a duty ratio of 75% or less and a frequency of 5 kHz or more and which has an effective power smaller than 500 W when performing pulse modulation. When performing the pulse modulation, the radio frequency power during the OFF level period may not be zero as long as it is lower than the radio frequency power during the ON level period. Further, the effective power when performing the pulse modulation is the magnitude of the radio frequency power multiplied by the duty ratio. For example, if the magnitude of the radio frequency power supplied in the form of the pulse wave is 1000 W and the duty ratio is 30%, the effective power is 300 W.

The second radio frequency power supply 23b is configured to generate a radio frequency power (radio frequency bias power) for ion attraction into the wafer W to supply the radio frequency bias power to the electrostatic chuck placing plate 13. A frequency of the radio frequency bias power is in the range of 400 kHz to 13.56 MHz, for example, 3 MHz. The second matching device 24b has a circuit configured to match an output impedance of the second radio frequency power supply 23b and an input impedance of a load side (the electrostatic chuck placing plate 13 side).

The above-described plasma processing apparatus 1 is equipped with the controller 100. The controller 100 is, for example, a computer and includes a program storage (not illustrated). The program storage stores programs which control processings of the wafer W in the plasma processing apparatus 1. Further, the program storage stores control programs for controlling various processings to be controlled by a processor, or programs, i.e., processing recipes, for operating the respective components of the plasma processing apparatus 1 to execute processings based on processing conditions. Furthermore, the programs may be recorded in a computer-readable recording medium and then installed from the recording medium to the controller 100.

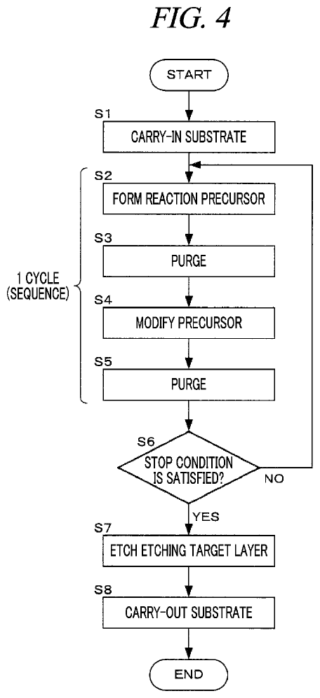

Hereinafter, a processing on the wafer W in the plasma processing apparatus 1 configured as described above will be described with reference to FIG. 4.

(Process S1)

First, as illustrated in FIG. 4, the wafer W is carried into the processing container 10. Specifically, in a state where the inside of the processing container 10 is exhausted to a vacuum atmosphere of a predetermined pressure, the gate valve 10c is opened, and the wafer W is transferred from a transfer chamber, which is in a vacuum atmosphere and adjacent to the processing container 10, onto the placing table 11 by a transfer mechanism. After the wafer W is transferred to the placing table 11 and the transfer mechanism is retreated from the processing container 10, the gate valve 10c is closed.

(Process S2)

Then, a reaction precursor containing Si is formed on the wafer W. Specifically, an Si source gas is supplied into the processing container 10 from a gas source selected from the plurality of gas sources of the gas source group 40 through the gas inlet hole 10a. Thus, an adsorption layer formed of the reaction precursor containing Si is formed on the wafer W. Further, the pressure within the processing container 10 is adjusted to a predetermined level by operating the exhaust device 53. The Si source gas is, for example, an aminosilane-based gas.

(Process S3)

Then, the space within the processing container 10 is purged. Specifically, the Si source gas in a gas phase is exhausted from the processing container 10. During the exhaustion, a rare gas, such as Ar gas, or an inert gas, such as nitrogen gas, may be supplied as a purge gas into the processing container 10. The process S3 may also be omitted.

(Process S4)

Thereafter, SiO₂ is formed on the wafer W by a plasma processing. Specifically, an O containing gas is supplied into the processing container 10 from a gas source selected from the plurality of gas sources of the gas source group 40 through the shower head 30. Moreover, the radio frequency power is supplied from the first radio frequency power supply 23a. Furthermore, the pressure within the processing container 10 is adjusted to a predetermined level by operating the exhaust device 53. Thus, plasma is formed from the O containing gas. Then, O radicals contained in the generated plasma modify the Si precursor formed on the wafer W. Specifically, the above-described precursor contains a bond of Si and H, and, thus, H of the precursor is substituted with O by the O radicals. Therefore, SiO₂ is formed on the wafer W. The O containing gas is, for example, a carbon dioxide (CO₂) gas or an oxygen (O₂) gas. Further, in the process S4, the continuously oscillating radio frequency power equal to or larger than 50 W and smaller than 500 W is supplied from the first radio frequency power supply 23a. Alternatively, in the process S4, the first radio frequency power supply 23a may supply the radio frequency power which is of the pulse wave shape having the duty ratio of 75% or less and the frequency of 5 kHz or more and which has the effective power smaller than 500 W.

The modification of the wafer W (precursor) with the O radicals is performed for a predetermined time period or more. The predetermined time period is previously determined depending on the magnitude of radio frequency power.

(Process S5)

Then, the space within the processing container 10 is purged. Specifically, the O containing gas is exhausted from the processing container 10. During the exhaustion, a rare gas, such as Ar gas, or an inert gas, such as nitrogen gas, may be supplied as a purge gas into the processing container 10. The process S5 may also be omitted.

By performing the cycle of the above-described processes S2 to S5 one or more times, an atomic layer of SiO₂ is deposited on the surface of the wafer W to form a SiO₂ film. Further, the number of times of performing the cycle is set depending on a desired film thickness of the SiO₂ film.

In the present exemplary embodiment, the O radicals that do not react with the wafer W within the processing container 10 during the process S4 are deactivated by being collided with the surface of the first member 61 and the second member 62 while passing through the flow path 60a of the partition wall 60, and then, discharged to the outside of the processing container 10. In other words, the partition wall 60 suppresses the O radicals in the processing space from reaching the exhaust opening 52 by only a linear movement along the exhaust path 54 during the process S4. The same is applied to the process S5 if the O radicals are present within the processing container 10. Therefore, it is possible to suppress the adhesion of the deposit derived from the O radicals to the portion at the exhaust-direction downstream side than the processing container 10 where it is difficult to remove the deposit by the dry cleaning.

(Process S6)

When the cycle of the above-described processes S2 to S5 is ended, it is determined whether a stop condition for the cycle is satisfied. Specifically, for example, it is determined whether the cycle is performed a predetermined number of times.

If the stop condition is not satisfied (if NO), the cycle of the processes S2 to S5 is performed again.

(Process S7)

If the stop condition is satisfied (if Yes), i.e., if the film formation is ended, a desired processing, such as etching on an etching target layer with the obtained SiO₂ film as a mask, is performed within the same processing container 10. The process S7 may also be omitted.

In the present exemplary embodiment, the etching is consecutively performed within the processing container 10 after the film formation. However, the film formation may be performed after the etching or between the etching and the etching.

(Process S8)

Then, the wafer W is carried out from the processing container 10 in reverse order from which the wafer W is carried into the processing container 10. Thus, the processing in the plasma processing apparatus 1 is ended.

Also, after the above-described processing is performed on a predetermined number of wafers W, a cleaning processing is performed on the plasma processing apparatus 1. Specifically, an F containing gas is supplied into the processing container 10 from a gas source selected from the plurality of gas sources of the gas source group 40. Further, the radio frequency power is supplied from the first radio frequency power supply 23a. Furthermore, the pressure of the space within the processing container 10 is adjusted to a predetermined level by operating the exhaust device 53. Thus, plasma is formed from the F element containing gas. Then, F radicals contained in the generated plasma decompose and remove the deposit derived from the O radicals adhering to the inside of the processing container 10. Further, even when the deposit adheres to the portion at the exhaust-direction downstream side than the processing container 10 during the cleaning, if the amount of the deposit is small, the deposit can be decomposed and removed by the F radicals. The decomposed deposit is discharged by the exhaust device 53.

Also, the above-described F containing gas is, for example, a CF₄ gas, an SF₆ gas, an NF₃ gas, or the like. The cleaning gas contains these F containing gases and may further contain an O containing gas, such as O₂ gas, or an Ar gas, if necessary. Further, during the cleaning, the pressure within the processing container 10 is in the range of one hundred to several hundred mTorr.

According to the present exemplary embodiment, the flow path 60a of the partition wall 60 is formed such that the exhaust opening 52 side cannot be seen from the processing space S side through the flow path 60a when viewed from the top, and the gas within the processing container 10 is discharged through flow path 60a. Therefore, the O radicals that do not react with the wafer W within the processing container 10 during the film formation are deactivated by being collided with the partition wall 60 while passing through the flow path 60a, and then, are discharged. Therefore, even if a large amount of O radicals is generated so as to react with the reaction precursor on the entire surface of the wafer W, it is possible to suppress the adhesion of the deposit derived from the O radicals to the place where it is difficult to remove the deposit by the dry cleaning, specifically, the portion at the exhaust-direction downstream side than the processing container 10. Therefore, it is possible to improve the productivity.

Also, in the method according to the present exemplary embodiment, it is possible to suppress the adhesion of the deposit to a wide area including the whole portion at the exhaust-direction downstream side than the partition wall 60.

Further, according to the present exemplary embodiment, the partition wall 60 is formed of a material, for example, metal, alumina or Si, having a high recombination coefficient for the O radicals. Thus, when the SiO₂ film is formed with the O radicals, it is possible to suppress the adhesion of the deposit derived from the O radicals to an unnecessary portion.

The partition wall 60 may be formed of a material having a low recombination coefficient for the F radicals. The material having the low recombination coefficient is, for example, alumina or quartz. Thus, even if the deposit derived from the O radicals adheres to the portion at the downstream side than the partition wall 60, the F radicals are not deactivated while passing through the flow path 60a during the process with the F radicals to reach the portion at the downstream side, and thus, can decompose and remove the deposit. Further, the process with the F radicals may be an etching process with the F radicals or the above-described dry cleaning process with the F radicals.

Since the partition wall 60 is formed of alumina, it is possible to more securely suppress the adhesion of the deposit derived from the O radicals. Also, even if the adhesion of the deposit occurs, the deposit can be removed during the process with the F radicals.

The partition wall 60 may be formed of different materials for the first member 61 and the second member 62, respectively. For example, the first member 61 may be formed of the material having the low recombination coefficient for the F radicals and the second member 62 may be formed of the material having the high recombination coefficient for the O radicals. More specifically, the first member 61 may be formed of quartz and the second member 62 may be formed of silicon. Otherwise, the first member 61 may be formed of the material having the high recombination coefficient for the O radicals and the second member 62 may be formed of the material having the low recombination coefficient for the F radicals. The first member 61 and the second member 62 may be formed of different materials, respectively, each having the high combination coefficient for the O radicals. Otherwise, the first member 61 and the second member 62 may be formed of different materials, respectively, each having the low combination coefficient for the F radicals.

Further, in consideration of the influence of metal on the wafer W, the first member 61 and the second member 62, particularly, the first member 61 closer to the wafer W, may be formed of a material that does not contain the metal.

Furthermore, in the present exemplary embodiment, the continuously oscillating radio frequency power equal to or larger than 50 W and smaller than 500 W is supplied as the power for plasma formation to the shower head 30. Thus, the O radicals having a sufficient amount to react with the reaction precursor on the entire surface of the wafer W and a small amount are generated within the processing container 10. Therefore, it is possible to further reduce the adhesion amount of the deposit derived from the O radicals in the portion at the exhaust-direction downstream side than the processing container 10.

In the present exemplary embodiment, the radio frequency power, which is of the pulse wave shape having the duty ratio of 75% or less and the frequency of 5 kHz or more and which has the effective power of less than 500 W, may be supplied as the power for plasma formation to the shower head 30. Even in this case, the O radicals having a sufficient amount to react with the reaction precursor on the entire surface of the wafer W and a small amount are generated within the processing container 10. Therefore, it is possible to further reduce the adhesion amount of the deposit derived from the O radicals in the portion at the exhaust-direction downstream side than the processing container 10.

(Evaluation test)

The present inventors conduct a test on the amounts of the deposit adhering to test pieces by attaching the test pieces to a plurality of portions within the plasma processing apparatus 1 and repeating the cycle of the above-described processes S2 to S5 600 times.

The conditions for this test are as follows.

Power for plasma formation of O radicals: continuously oscillating radio frequency power of 150 W

Material of the first member 61: quartz

Material of the second member 62: silicon

Gas used in the process S4 and its flow rate: O containing gas of 290 sccm and Ar gas of 40 sccm

Pressure within the processing container 10 in the process S4: 200 mTorr

Further, in this test, attachment positions of the test pieces and the amounts of the deposit adhering to the test pieces are as follows. Furthermore, all of the attachment positions of the test pieces are located outside the processing space S where the plasma is formed.

Bottom wall of a manifold forming the exhaust opening 52: 4.9 nm

Inner peripheral wall of the manifold: 11.2 nm

Portion between the side wall of the processing container 10 and the shield 50 and approximately equal in height to the wafer W on the placing table 11: 4.1 nm

Further, the plasma processing apparatus 1, if the first member 61 and the second member 62 are not provided in the partition wall 60, when the cycle of the processes S2 to S5 is repeated 600 times under the same conditions, the deposit of 80 nm or more adheres to the test pieces attached to the above-described positions.

Therefore, according to the evaluation test, the amount of the deposit adhering to the outside of the processing space S is reduced.

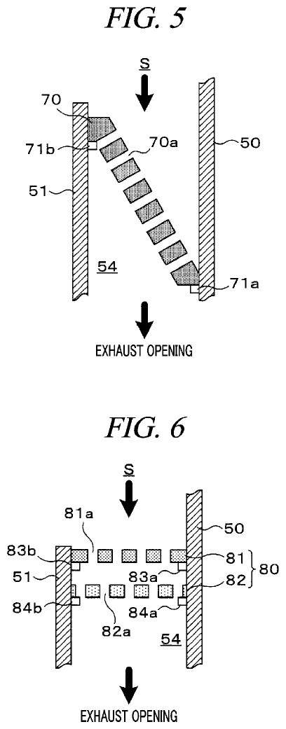

FIG. 5 shows another example of a partition wall.

A partition wall 70 illustrated in FIG. 5 is composed of a single member unlike the example illustrated in FIG. 2, and includes through-holes 70a extended in a direction intersecting the extension direction of the exhaust path 54. Specifically, the partition wall 70 is configured as a flat plate including the through-holes 70a penetrating straightly from a front surface to a rear surface thereof to be slanted toward the exhaust path 54, so that an extension direction of the through-holes 70a intersects the extension direction of the exhaust path 54. Further, the through-holes 70a form a flow path for connecting the processing space S side and the exhaust opening 52 side of the exhaust path 54, and the flow path is formed such that the exhaust opening 52 side cannot be seen from the processing space S side through the flow path when viewed from the top. The partition wall 70 can also suppress the adhesion of the deposit derived from the O radicals. Also, the partition wall 70 is formed by slanting the flat plate including the through-holes 70a, and, thus, it is possible to enhance exhaust conductance of the partition wall 70 and promote the deactivation of the radicals by the partition wall 70.

Further, in the example illustrated in the drawing, a support supporting the partition wall 70 includes an outer protrusion 71a that protrudes inwards from the shield 50 and supports an outer end of the partition wall 70 and an inner protrusion 71b that protrudes outwards from the shield 51 and supports an inner end of the partition wall 70.

FIG. 6 shows yet another example of a partition wall.

A partition wall 80 illustrated in FIG. 6 is composed of two segments 81 and 82 divided along a flow of a gas from the processing space S side to the exhaust opening 52 side. Also, the segments 81 and 82 respectively include through-hoes 81a and 82a extended along the flow. The through-holes 81a of the segment 81 are formed not to overlap the through-holes 82a of the segment 82 when the extension direction of the exhaust path 54 is viewed from the top. Further, the through-hoes 81a and 82a form a flow path for connecting the processing space S side and the exhaust opening 52 side of the exhaust path 54, and the flow path is formed such that the exhaust opening 52 side cannot be seen from the processing space S side through the flow path when viewed from the top. The partition wall 80 can also suppress the adhesion of the deposit derived from the O radicals.

The through-holes 81a and 82a are formed along the extension direction of the exhaust path 54, but may be extended along a direction intersecting the extension direction of the exhaust path 54. Thus, it is possible to enhance the exhaust conductance of the partition wall 80.

The number of segments of the partition wall 80 divided along the flow of the gas from the processing space S side to the exhaust opening 52 side is two in the example illustrated in the drawing, but may be three or more.

Further, in the example illustrated in the drawing, a support supporting the segment 81 includes an outer protrusion 83a that protrudes inwards from the shield 50 and supports an outer end of the segment 81 and an inner protrusion 83b that protrudes outwards from the shield 51 and supports an inner end of the segment 81. Also, a support supporting the segment 82 includes an outer protrusion 84a that protrudes inwards from the shield 50 and supports an outer end of the segment 82 and an inner protrusion 84b that protrudes outwards from the shield 51 and supports an inner end of the segment 82.

In the above-described exemplary embodiments, the plasma processing apparatus 1 may perform the etching after the film formation or may perform the etching before the film formation. Otherwise, the plasma processing apparatus 1 may perform the etching before and after the film formation or may perform only film formation without the etching.

In the above-described exemplary embodiments, the plasma processing apparatus 1 uses capacitively coupled plasma for the film formation and the etching. However, the plasma processing apparatus 1 may use inductively coupled plasma or surface wave plasma, such as microwave, for the film formation and the etching.

Further, in the above-described exemplary embodiments, the SiO₂ film is formed with the O radicals, but the film formation may be performed with other radicals.

Furthermore, in the above-described exemplary embodiments, the shield 50 and the shield 51 are formed of aluminum coated with ceramic such as Y₂O₃. However, the shield 50 and the shield 51 may be formed of materials each having the high recombination coefficient for the O radicals or materials each having the low recombination coefficient for the F radicals like the first member 61 and the second member 62.

It should be understood that the exemplary embodiments disclosed herein are illustrative in all aspects and do not limit the present disclosure. The above-described exemplary embodiments may be omitted, substituted, or changed in various forms without departing from the scope and spirit of the appended claims.

Also, the following configurations also belong to the technical scope of the present disclosure.

(1) A film forming apparatus configured to form a predetermined film on a substrate by PEALD, comprising:

a processing container configured to airtightly accommodate therein the substrate; and

a placing table on which the substrate is placed within the processing container,

wherein the processing container includes:

an exhaust opening through which an inside of the processing container is exhausted;

an exhaust path configured to connect the exhaust opening and a processing space located above the placing table within the processing container; and

a partition wall configured to separate a processing space side from an exhaust opening side in the exhaust path, and

wherein the partition wall includes a flow path configured to connect the processing space side and the exhaust opening side, and

the partition wall is formed such that the exhaust opening side is not seen from the processing space side when an extension direction of the exhaust path is viewed from a top.

In the above-described configuration (1), the partition wall configured to separate the processing space side from the exhaust opening side in the exhaust path includes the flow path configured to connect the processing space side and the exhaust opening side, and is formed such that the exhaust opening side cannot be seen from the processing space side when the extension direction of the exhaust path is viewed from the top. Therefore, the radicals that did not react with the wafer W in the radicals generated in the processing container are deactivated by being collided with the partition wall while passing through the flow path and then discharged. Therefore, even if the radicals are supplied in a large amount to put the substrate into saturation, it is possible to suppress the adhesion of the deposit derived from the radicals to the unnecessary portion. Thus, it is possible to improve the productivity.

(2) The film forming apparatus described in the above (1), wherein the partition wall includes a first member extended from a first side wall toward a second side wall to cover a part of the exhaust path and a second member extended from the second side wall toward the first side wall to cover a part of the exhaust path, the first side wall and the second side wall forming the exhaust path,

a tip end portion of the first member and a tip end portion of the second member overlap with each other when viewed from the top, and

the flow path is formed by a gap between the first member and the second side wall and a gap between the second member and the first side wall.

(3) The film forming apparatus described in the above (1), wherein through-holes extended in a direction intersecting the extension direction of the exhaust path are included, and

the flow path is formed by the through-holes.

(4) The film forming apparatus described in the above (1), wherein the partition wall includes multiple segments divided along a flow of a gas from the processing space side to the exhaust opening side,

each of the multiple segments includes through-holes,

the through-holes of at least one of the multiple segments are not overlapped with the through-holes of others of the multiple segments when viewed from the top, and

the flow path is formed by the through-holes of the multiple segments.

(5) The film forming apparatus described in any one of the above (1) to (4), wherein the partition wall is formed of metal, alumina or silicon.

Therefore, when the film formation is performed with the O radicals, it is possible to more securely suppress the adhesion of the deposit derived from the O radicals to the unnecessary portion.

(6) The film forming apparatus described in any one of the above (1) to (4), wherein the partition wall is formed of alumina or quartz.

Therefore, during the process with the F radical, the F radicals are not deactivated while passing through the flow path 60a and reach the portion at the downstream side and thus can decompose and remove the deposit.

(7) The film forming apparatus described in any one of the above (1) to (4), wherein the partition wall is formed of alumina.

Therefore, it is possible to more securely suppress the adhesion of the deposit derived from the O radicals. Also, even if the adhesion of the deposit occurs, the deposit can be removed during the process with the F radicals.

(8) The film forming apparatus described in any one of the above (1) to (7), further comprising:

a plasma source configured to form plasma from a gas for film formation within the processing container;

a radio frequency power supply configured to supply a radio frequency power for plasma formation to the plasma source; and

a controller configured to control the radio frequency power supply to supply a continuously oscillating radio frequency power equal to or larger than 50 W and smaller than 500 W to the plasma source.

Therefore, it is possible to further reduce the adhesion amount of the deposit derived from the radicals in the portion at an exhaust-direction downstream side than the partition wall.

(9) The film forming apparatus described in any one of the above (1) to (7), further comprising:

a plasma source configured to form plasma from a gas for film formation within the processing container;

a radio frequency power supply configured to supply a radio frequency power for plasma formation to the plasma source; and

a controller configured to control the radio frequency power supply to supply a radio frequency power, which is of a pulse wave shape having a duty ratio of 75% or less and a frequency of 5 kHz or more and which has an effective power smaller than 500 W, as the power for plasma formation to the plasma source.

Therefore, it is possible to further reduce the adhesion amount of the deposit derived from the radicals in the portion at the exhaust-direction downstream side than the partition wall.

(10) A film forming method of forming a predetermined film on a substrate in a film forming apparatus by PEALD,

wherein the film forming apparatus includes:

a processing container configured to airtightly accommodate therein the substrate; and

a placing table on which the substrate is placed within the processing container, and

wherein the processing container includes:

an exhaust opening through which an inside of the processing container is exhausted;

an exhaust path configured to connect the exhaust opening and a processing space located above the placing table within the processing container; and

a partition wall configured to separate a processing space side and an exhaust opening side in the exhaust path,

wherein the partition wall includes a flow path configured to allow a gas to pass from the processing space side to the exhaust opening side, and

the partition wall is formed such that the exhaust opening side is not seen from the processing space side when an extension direction of the exhaust path is viewed from a top, and

wherein the film forming method includes:

forming plasma from a gas for film formation within the processing container and processing a surface of the substrate with radicals contained in the plasma; and

discharging the gas, which is formed into the plasma, through the flow path of the partition wall after the processing of the surface of the substrate.

Therefore, even if the radicals are supplied in a large amount to put the substrate into the saturation, it is possible to suppress the adhesion of the deposit derived from the radicals to the unnecessary portion.

### EXPLANATION OF CODES

1: Plasma processing apparatus

10: Processing container

11: Placing table

52: Exhaust opening

54: Exhaust path

60, 70, 80: Partition wall

S: Processing space

W: Wafer

1. A film forming apparatus configured to form a predetermined film on a substrate by PEALD, comprising:
a processing container configured to airtightly accommodate therein the substrate; and
a placing table on which the substrate is placed within the processing container,
wherein the processing container includes:
an exhaust opening through which an inside of the processing container is exhausted;
an exhaust path configured to connect the exhaust opening and a processing space located above the placing table within the processing container; and
a partition wall configured to separate a processing space side from an exhaust opening side in the exhaust path, and
wherein the partition wall includes a flow path configured to connect the processing space side and the exhaust opening side, and
the partition wall is formed such that the exhaust opening side is not seen from the processing space side when an extension direction of the exhaust path is viewed from a top.

2. The film forming apparatus of claim 1,
wherein the partition wall includes a first member extended from a first side wall toward a second side wall to cover a part of the exhaust path and a second member extended from the second side wall toward the first side wall to cover a part of the exhaust path, the first side wall and the second side wall forming the exhaust path,
a tip end portion of the first member and a tip end portion of the second member overlap with each other when viewed from the top, and
the flow path is formed by a gap between the first member and the second side wall and a gap between the second member and the first side wall.

3. The film forming apparatus of claim 1,
wherein the partition wall includes through-holes extended in a direction intersecting the extension direction of the exhaust path, and
the flow path is formed by the through-holes.

4. The film forming apparatus of claim 1,
wherein the partition wall includes multiple segments divided along a flow of a gas from the processing space side to the exhaust opening side,
each of the multiple segments includes through-holes,
the through-holes of at least one of the multiple segments are not overlapped with the through-holes of others of the multiple segments when viewed from the top, and
the flow path is formed by the through-holes of the multiple segments.

5. The film forming apparatus of claim 1,
wherein the partition wall is formed of metal, alumina or silicon.

6. The film forming apparatus of claim 1,
wherein the partition wall is formed of alumina or quartz.

7. The film forming apparatus of claim 1,
wherein the partition wall is formed of alumina.

8. The film forming apparatus of claim 1, further comprising:
a plasma source configured to form plasma from a gas for film formation within the processing container;
a radio frequency power supply configured to supply a radio frequency power for plasma formation to the plasma source; and
a controller configured to control the radio frequency power supply to supply a continuously oscillating radio frequency power equal to or larger than 50 W and smaller than 500 W to the plasma source.

9. The film forming apparatus of claim 1, further comprising:
a plasma source configured to form plasma from a gas for film formation within the processing container;
a radio frequency power supply configured to supply a radio frequency power for plasma formation to the plasma source; and
a controller configured to control the radio frequency power supply to supply a radio frequency power, which is of a pulse wave shape having a duty ratio of 75% or less and a frequency of 5 kHz or more and which has an effective power smaller than 500 W, as the power for plasma formation to the plasma source.

10. (canceled)

11. The film forming apparatus of claim 2,
wherein the first member and the second member are formed of different materials.

12. The film forming apparatus of claim 2,
wherein the first member is formed of quartz, and the second member is formed of silicon or metal.

13. The film forming apparatus of claim 2,
wherein the first member is formed of quartz, and the second member is formed of silicon.

14. The film forming apparatus of claim 13, further comprising:
a support member configured to support the placing table;
a first shield provided at an inner wall of the processing container; and
a second shield provided at an outer circumference surface of the support member,
wherein the first side wall is the first shield, and
the second side wall is the second shield.

15. The film forming apparatus of claim 14,
wherein the first member is supported by a first support provided at the first shield, and
the second member is supported by a second support provided at the second shield.

16. The film forming apparatus of claim 15,
wherein the first member is provided at a position higher than the second member.

17. A film forming method of forming a predetermined film on a substrate in a film forming apparatus by PEALD,
wherein the film forming apparatus includes:
a processing container configured to airtightly accommodate therein the substrate; and
a placing table on which the substrate is placed within the processing container, and
wherein the processing container includes:
an exhaust opening through which an inside of the processing container is exhausted;
an exhaust path configured to connect the exhaust opening and a processing space located above the placing table within the processing container; and
a partition wall configured to separate a processing space side and an exhaust opening side in the exhaust path,
wherein the partition wall includes a flow path configured to allow a gas to pass from the processing space side to the exhaust opening side, and
the partition wall is formed such that the exhaust opening side is not seen from the processing space side when an extension direction of the exhaust path is viewed from a top, and
wherein the film forming method includes:
forming plasma from a gas for film formation within the processing container and processing a surface of the substrate with radicals contained in the plasma; and
discharging the gas, which is formed into the plasma, through the flow path of the partition wall after the processing of the surface of the substrate.
